(19) United States
(12) Patent Application Publication
(10) Pub. No.: US 2023/0137476 A1
(43) Pub. Date: May 4, 2023

(54) DISPLAY DEVICE

(71) Applicant: Samsung Display Co., LTD., Yongin-si (KR)

(72) Inventor: Jung-Mi CHOI, Seoul (KR)

(73) Assignee: Samsung Display Co., LTD., Yongin-si (KR)

(21) Appl. No.: 17/859,671

(22) Filed: Jul. 7, 2022

(30) Foreign Application Priority Data
Nov. 3, 2021 (KR) 10-2021-0149664

(51) Int. Cl. H01L 27/32; H01L 51/52

(52) U.S. Cl. CPC H01L 27/3246; H01L 51/52; H01L 51/5284

(57) ABSTRACT

A display device includes a first barrier layer disposed on a first substrate, a second substrate disposed on the first barrier layer, a second barrier layer disposed on the second substrate, a buffer layer disposed on the second barrier layer, an upper charge trap layer disposed on the buffer layer, the upper charge trap layer including silicon oxide, and having an oxygen atom content in a range of about 54 at % to about 56 at %, a semiconductor layer disposed on the upper charge trap layer, a pixel electrode disposed on the semiconductor layer and electrically connected to the semiconductor layer, a pixel defining layer disposed on the pixel electrode, the pixel defining layer including an opening exposing a portion of the pixel electrode, and having a black color, an intermediate layer disposed on the pixel electrode and disposed in the opening and a common electrode disposed on the intermediate layer.

### CROSS REFERENCE TO RELATED APPLICATION(S)

This application claims priority to and benefits of Korean Patent Application No. 10-2021-0149664 under 35 U.S.C. § 119, filed on Nov. 3, 2021, in the Korean Intellectual Property Office (KIPO), the entire contents of which are incorporated herein by reference.

### BACKGROUND

### 1. Technical Field

The disclosure relates to an organic light emitting display device.

### 2. Description of the Related Art

With an advancement of technology, display devices that are smaller in size, lighter in weight, and have better performance are being produced. Until now, a CRT television has been widely used as a display device with many advantages in terms of performance and price. A display device that overcomes shortcomings of the CRT television in terms of miniaturization or portability and has advantages such as miniaturization, weight reduction, and low power consumption is attracting attention. For example, a plasma display device, a liquid crystal display device, an organic light emitting display device, a quantum dot display device, etc. are attracting attention. Recently, a display device having improved afterimage and improved luminance has been demanded.

### SUMMARY

Embodiments may provide a display device with improved durability.

An embodiment of a display device may include a first barrier layer disposed on a first substrate, a second substrate disposed on the first barrier layer, a second barrier layer disposed on the second substrate, a buffer layer disposed on the second barrier layer, an upper charge trap layer disposed on the buffer layer, the upper charge trap layer including silicon oxide, and having an oxygen atom content in a range of about 54 at % to about 56 at %, a semiconductor layer disposed on the upper charge trap layer, a pixel electrode disposed on the semiconductor layer and electrically connected to the semiconductor layer, a pixel defining layer disposed on the pixel electrode, the pixel defining layer including an opening exposing a portion of the pixel electrode, and having a black color, an intermediate layer disposed on the pixel electrode and disposed in the opening and a common electrode disposed on the intermediate layer.

In an embodiment, the pixel defining layer may include a black pigment.

In an embodiment, the black pigment may include carbon black.

In an embodiment, an optical density of the pixel defining layer may be about 1.

In an embodiment, at least a portion of the pixel defining layer may overlap the semiconductor layer.

In an embodiment, the upper charge trap layer may include a hydrogen atom (H) and a nitrogen atom (N), and a ratio of N—H bonds in the upper charge trap layer may be about 0.3 at % or less.

In an embodiment, the display device may further include a lower charge trap layer disposed between the first substrate and the buffer layer, the lower charge trap layer including silicon nitride.

In an embodiment, the lower charge trap layer may be formed under an ammonia-free (NH₃ free) condition.

In an embodiment, a ratio of a silicon atom content in the lower charge trap layer to a nitrogen atom content in the lower charge trap layer may be in a range of about 1.6 to about 2.5.

In an embodiment, a silicon atom content in the lower charge trap layer may be in a range of about 60 at % to about 70 at %, and a nitrogen atom content in the lower charge trap layer may be in a range of about 25 at % to about 35 at %.

In an embodiment, a ratio of Si—H bond in the lower charge trap layer may be in a range of about 8 at % to about 15 at %.

In an embodiment, a ratio of the Si—H bond in the lower charge trap layer to the N—H bond in the lower charge trap layer may be in a range of about 8 to about 15.

In an embodiment, the lower charge trap layer may be disposed between the first barrier layer and the second substrate.

In an embodiment, the lower charge trap layer may be disposed between the second substrate and the second barrier layer.

In an embodiment, the lower charge trap layer may be disposed on the second barrier layer.

In an embodiment, the first barrier layer and the second barrier layer may include silicon oxide.

In an embodiment, the first substrate and the second substrate may include polyimide.

In an embodiment, the upper charge trap layer may be in contact with the semiconductor layer.

In an embodiment, the buffer layer may include silicon nitride.

In an embodiment, the semiconductor layer may include polycrystalline silicon or an oxide semiconductor.

The display device according to an embodiment may include a charge trap layer and a pixel defining layer having a black color. The charge trap layer may improve a long-term afterimage of the display device. The pixel defining layer having a black color may improve the long-term afterimage and the instantaneous afterimage of the display device. The pixel defining layer having a black color may prevent a luminance drop phenomenon occurring when the display device includes the charge trap layer. Accordingly, the display quality of the display device may be improved.

### BRIEF DESCRIPTION OF THE DRAWINGS

Illustrative, non-limiting embodiments will be more clearly understood from the following detailed description taken in conjunction with the accompanying drawings.

FIG. 1 is a plan view illustrating a display device according to an embodiment.

FIG. 2 is a schematic cross-sectional view taken along line I-I′ of FIG. 1.

FIG. 3 is a schematic view for describing an afterimage of a display device.

FIG. 4 is a graph for explaining a long-term afterimage of a display device.

FIG. 5 is a graph illustrating an example of FIG. 4.

FIG. 6 is a graph illustrating a degree of an afterimage depending on whether a pixel defining layer has a black color, according to an embodiment.

FIG. 7 is a graph illustrating a degree of an afterimage depending on whether a pixel defining layer has a black color, according to an embodiment.

FIG. 8 is a graph for explaining an instantaneous afterimage of a display device.

FIG. 9 is a graph illustrating an afterimage time depending on whether a pixel defining layer has a black color, according to an embodiment.

FIG. 10 is a schematic cross-sectional view illustrating a display device according to an embodiment.

FIG. 11 is a schematic cross-sectional view illustrating a display device according to an embodiment.

FIG. 12 is a schematic cross-sectional view illustrating a display device according to an embodiment.

### DETAILED DESCRIPTION OF THE EMBODIMENTS

The disclosure now will be described more fully hereinafter with reference to the accompanying drawings, in which various embodiments are shown. This disclosure may, however, be embodied in many different forms, and should not be construed as limited to the embodiments set forth herein. Rather, these embodiments are provided so that this disclosure will be thorough and complete, and will fully convey the scope of the disclosure to those skilled in the art. Like reference numerals refer to like elements throughout.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

Also, when an element is referred to as being “in contact” or “contacted” or the like to another element, the element may be in “electrical contact” or in “physical contact” with another element; or in “indirect contact” or in “direct contact” with another element.

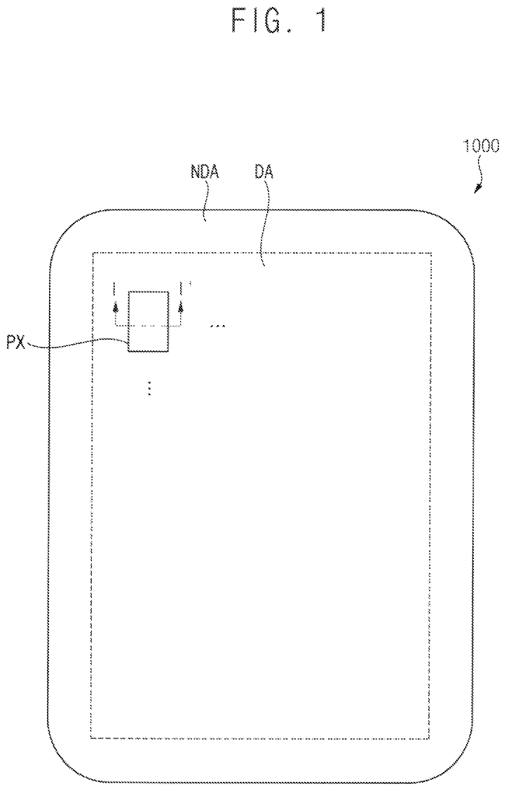

FIG. 1 is a plan view illustrating a display device according to an embodiment.

Referring to FIG. 1, the display device 1000 according to an embodiment of the disclosure may include a display area DA and a non-display area NDA.

A pixel PX may be disposed in the display area DA. The pixel PX may emit light. The display area DA may display an image.

The non-display area NDA may surround at least a portion of the display area DA. Drivers (not shown) may be disposed in the non-display area NDA. The drivers may be bent toward a rear surface of the display device 1000 so as not to be viewed in a plan view of the display device 1000. The drivers may provide a signal and/or a voltage to the pixel PX. The pixel PX may emit light based on a signal and/or a voltage provided from the drivers. For example, the drivers may include a gate driver, a data driver, a light emitting driver, a power voltage generator, a timing controller, and the like. The non-display area NDA may not display an image.

The display device 1000 may include an organic light emitting display device, an inorganic light emitting display device, a quantum dot light emitting display device, a micro LED display device, a nano LED display device, a plasma display device, a liquid crystal display device, and the like.

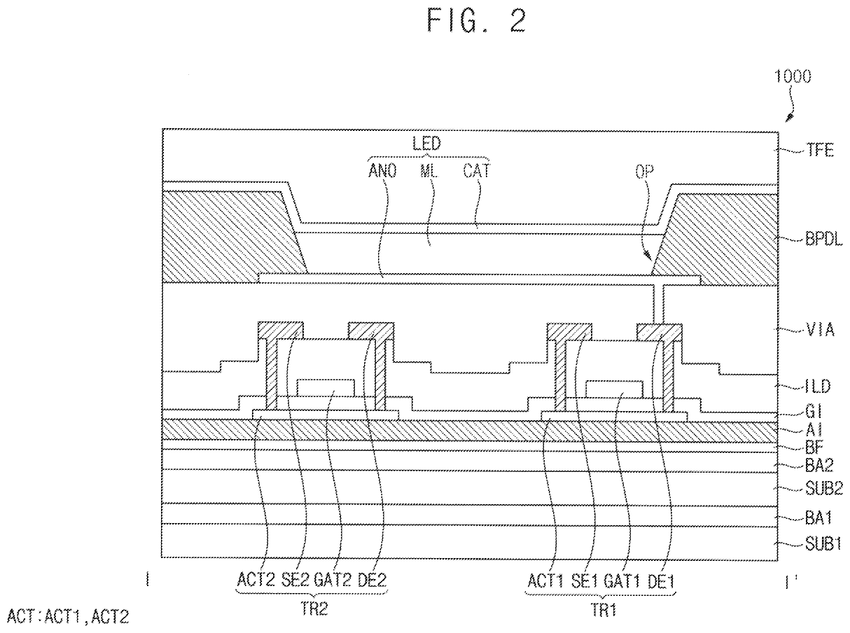

FIG. 2 is a schematic cross-sectional view taken along line I-I′ of FIG. 1.

Referring to FIG. 2, the display device 1000 may include a first substrate SUB1, a first barrier layer BA1, a second substrate SUB2, a second barrier layer BA2, a buffer layer BF, a charge trap layer AI, a first transistor TR1, a second transistor TR2, a gate insulating layer GI, an interlayer insulating layer ILD, a via insulating layer VIA, a light emitting element LED, a pixel defining layer BPDL, and a thin film encapsulation layer TFE.

The first transistor TR1 may include a first active pattern ACT1, a first gate electrode GAT1, a first source electrode SE1, and a first drain electrode DE1. The first transistor TR1 may be a driving transistor.

The second transistor TR2 may include a second active pattern ACT2, a second gate electrode GAT2, a second source electrode SE2, and a second drain electrode DE2. The second transistor TR2 may be a switching transistor.

A semiconductor layer ACT may include a first active pattern ACT1 and a second active pattern ACT2.

The light emitting element LED may include a pixel electrode ANO, an intermediate layer ML, and a common electrode CAT.

In an embodiment, the first substrate SUB1 may include a polymer material. Examples of the polymer material may include polyimide, polyethersulphone, polyacrylate, polyarylate, polyetherimide, polyethylene naphthalate, polyethylene terephthalate, polyphenylene sulfide, polyallylate, polycarbonate, cellulose triacetate, cellulose acetate propionate, and the like. These may be used alone or in combination with each other. However, the polymer material is not limited thereto.

In another embodiment, the first substrate SUB1 may include glass, quartz, or the like.

The first substrate SUB may have a thickness of about 10 micrometers.

The first barrier layer BA1 may be disposed on the first substrate SUB1. The first barrier layer BA1 may cover the first substrate SUB1. The first barrier layer BA1 may prevent diffusion of impurity ions and may prevent penetration of moisture or air. The first barrier layer BA1 may include an inorganic material. Examples of the inorganic material may include silicon oxide (SiOx), silicon nitride (SiNx), and silicon oxynitride (SiOxNy). These may be used alone or in combination with each other.

Although not illustrated, the first barrier layer BA1 may include a lower barrier layer and an upper barrier layer. The lower barrier layer may include silicon oxide. The upper barrier layer may be disposed on the lower barrier layer, and may include silicon nitride. The lower barrier layer may have a thickness of approximately 6000 angstroms. The upper barrier layer may have a thickness of approximately 150 angstroms.

The second substrate SUB2 may be disposed on the first barrier layer BA1. The first substrate SUB1 and the second substrate SUB2 may include substantially the same material. The second substrate SUB2 may have a thickness of about 5 micrometers to about 6 micrometers. For example, the second substrate SUB2 may have a thickness of approximately 5.8 micrometers.

The second barrier layer BA2 may be disposed on the second substrate SUB2. The second barrier layer BA2 may include substantially the same material as the first barrier layer BA1. For example, the second barrier layer BA2 may include silicon oxide. The second barrier layer BA2 may have a thickness of about 5000 angstroms.

The buffer layer BF may be disposed on the second barrier layer BA2. The buffer layer BF may cover the second barrier layer BA2. In an embodiment, the buffer layer BF may include silicon nitride. However, the material included in the buffer layer BF is not limited thereto, and the buffer layer BF may include silicon oxide, silicon oxynitride, or the like. The buffer layer BF may have a thickness of about 350 angstroms. The buffer layer BF may prevent metal atoms or impurities from diffusing into the semiconductor layer ACT. Also, the buffer layer BF may control the rate of heat provided to the semiconductor layer ACT during a crystallization process for forming the semiconductor layer ACT.

The charge trap layer AI may be disposed on the buffer layer BF. The charge trap layer AI may include an inorganic material. In an embodiment, the charge trap layer AI may include silicon oxide. However, the inorganic material is not limited to silicon oxide, and may be silicon nitride, silicon oxynitride, or the like. The charge trap layer AI may have a thickness of about 3500 angstroms.

In case that the charge trap layer AI includes silicon oxide, the charge trap layer AI may be formed by chemical vapor deposition. The charge trap layer AI may be formed by adjusting the input amounts of nitrous oxide (N₂O) and silane (SiH₄). Accordingly, the charge trap layer AI may include a hydrogen atom (H) and a nitrogen atom (N) in addition to an oxygen atom (O) and a silicon atom (Si).

In case that the charge trap layer AI includes silicon oxide, a ratio of N—H bond in the charge trap layer AI may be about 0.3 at % or less, or about 0.1 at % to about 0.2 at %. However, the ratio of the N—H bond in the charge trap layer AI is not limited thereto. Here, the ratio of N—H bond may mean a ratio of bond between a nitrogen atom (N) and a hydrogen atom (H) among all bonds. The ratio of N—H bond may be analyzed through a Fourier transform infrared spectrometer (FT-IR spectrometer).

In case that the charge trap layer AI includes silicon oxide, the oxygen atom content in the charge trap layer AI may be about 55.27 at %, or in a range of about 54 at % to about 56 at %. The silicon atom content in the charge trap layer AI may be in a range of about 44.72 at %, or in a range of about 43 at % to about 45 at %.

In an embodiment, the charge trap layer AI may be in contact with the semiconductor layer ACT.

A nitrogen atom (N) may be disposed at an interface between the charge trap layer AI and the semiconductor layer ACT. The nitrogen atom (N) positioned at the interface may have an outermost electron that is not bonded to other atoms. Some of the outermost electrons of the nitrogen atom (N) positioned at the interface may have a tendency to be stabilized by binding to the external electrons (—). For example, as the number of nitrogen atoms (N) positioned at the interface increases, more electrons (—) may be trapped in the charge trap layer AI. Accordingly, in case that the ratio of N—H bond in the charge trap layer AI has the above-described value or is within the above-described range, the amount of charge trapping in the charge trap layer AI may increase.

As the display device 1000 includes the charge trap layer AI, element characteristics of the first transistor TR1 may be improved. For example, a driving range of the first transistor TR1 may increase. For example, as the charge trap layer AI is disposed, a relatively large driving current may flow through the first transistor TR1 to which the same data voltage is applied. Accordingly, a luminance of the display device 1000 (refer to FIG. 1) may be improved, and a long-term afterimage may be improved. A detailed description thereof will be given later.

As the ratio of the N—H bond in the charge trap layer AI, the oxygen atom content in the charge trap layer AI, and/or the silicon atom content in the charge trap layer AI have the above-mentioned values or are within the above-described ranges, the element characteristics of the first transistor TR1 may be improved. For example, in case that the ratio of the N—H bond in the charge trap layer AI, the oxygen atom content in the charge trap layer AI, and/or the silicon atom content in the charge trap layer AI are smaller than the above-described range, the improvement of the device characteristics of the first transistor TR1 may not be significant, and in case that the ratio of the N—H bond in the charge trap layer AI, the oxygen atom content in the charge trap layer AI, and/or the silicon atom content in the charge trap layer are larger than the above-described range, the charge trap layer AI may not be properly formed.

The semiconductor layer ACT may be disposed on the charge trap layer AI. The semiconductor layer ACT may be in contact with the charge trap layer AI. The semiconductor layer ACT may include a first active pattern ACT1 and a second active pattern ACT2. In an embodiment, the first active pattern ACT1 and the second active pattern ACT2 may include polycrystalline silicon. In another embodiment, the first active pattern ACT1 may include polycrystalline silicon, and the second active pattern ACT2 may include an oxide semiconductor. However, the disclosure is not limited thereto, and the semiconductor layer ACT may include amorphous silicon.

The gate insulating layer GI may be disposed on the semiconductor layer ACT and may cover the semiconductor layer ACT. The gate insulating layer GI may include an inorganic material. Examples of the inorganic material may include silicon oxide, silicon nitride, and silicon oxynitride. These may be used alone or in combination with each other.

The first gate electrode GAT1 and the second gate electrode GAT2 may be disposed on the gate insulating layer GI. The first gate electrode GAT1 may overlap a portion of the first active pattern ACT1, and the second gate electrode GAT2 may overlap a portion of the second active pattern ACT2. The first gate electrode GAT1 and the second gate electrode GAT2 may include a metal, a metal oxide, a metal nitride, or a combination thereof. Examples of the metal may include silver, molybdenum, aluminum, tungsten, copper, nickel, chromium, titanium, tantalum, platinum, and scandium. These may be used alone or in combination with each other. Examples of the metal oxide may include indium tin oxide (ITO), indium zinc oxide (IZO), and the like. These may be used alone or in combination with each other. Examples of the metal nitride include aluminum nitride, tungsten nitride, and chromium nitride. These may be used alone or in combination with each other.

The interlayer insulating layer ILD may be disposed on the first gate electrode GAT1 and the second gate electrode GAT2, and may cover the first gate electrode GAT1 and the second gate electrode GAT2. The interlayer insulating layer ILD may include an inorganic material.

The first and second source electrodes SE1 and SE2 and the first and second drain electrodes DE1 and DE2 may be disposed on the interlayer insulating layer ILD. Each of the first and second source electrodes SE1 and SE2 and the first and second drain electrodes DE1 and DE2 may be electrically connected to the semiconductor layer ACT through a contact hole. For example, the first drain electrode DE1 may be electrically connected to the first active pattern ACT1. Each of the first and second source electrodes SE1 and SE2 and each of the first and second drain electrodes DE1 and DE2 may include a metal, a metal oxide, a metal nitride, or a combination thereof.

The via insulating layer VIA may be disposed on the first and second source electrodes SE1 and SE2 and the first and second drain electrodes DE1 and DE2. The via insulating layer VIA may cover the first and second source electrodes SE1 and SE2 and the first and second drain electrodes DE1 and DE2. The via insulating layer VIA may have a substantially flat top surface. The via insulating layer VIA may include an organic material. Examples of the organic material may include photoresists, polyacrylic resins, and polyimide resins. These may be used alone or in combination with each other.

The pixel electrode ANO may be disposed on the via insulating layer VIA. The pixel electrode ANO may be electrically connected to the first drain electrode DE1 through a contact hole. Accordingly, the pixel electrode ANO may be electrically connected to the first active pattern ACT1 of the semiconductor layer ACT through the first drain electrode DE1. The pixel electrode ANO may include a metal, a metal oxide, a metal nitride, or a combination thereof. For example, the pixel electrode ANO may be an anode electrode. In another example, the pixel electrode ANO may be a cathode electrode.

The pixel defining layer BPDL may be disposed on the via insulating layer VIA and the pixel electrode ANO. The pixel defining layer BPDL may cover an end of the pixel electrode ANO. The pixel defining layer BPDL may expose the pixel electrode ANO through an opening OP. In an embodiment, at least a portion of the pixel defining layer BPDL may overlap the semiconductor layer ACT.

In an embodiment, the pixel defining layer BPDL may absorb external light incident on the display device 1000. For example, the pixel defining layer BPDL may absorb external light to reduce the amount of the external light incident to the semiconductor layer ACT. The pixel defining layer BPDL may have a black color. The pixel defining layer BPDL may include a black pigment having a black color. Examples of the black pigment may include carbon black. However, the black pigment is not limited thereto.

In an embodiment, the optical density (OD) of the pixel defining layer BPDL may be approximately 1. For example, about 10% of the external light incident on the pixel defining layer BPDL may pass through the pixel defining layer BPDL. However, the absorbance of the pixel defining layer BPDL is not limited.

As the display device 1000 includes the pixel defining layer BPDL having a black color, the long-term afterimage may be further improved. A detailed description thereof will be given later.

The intermediate layer ML may be disposed on the pixel electrode ANO. The intermediate layer ML may be disposed in the opening OP of the pixel defining layer BPDL. The intermediate layer ML may include a hole injection layer, a hole transport layer, a light emitting layer, an electron transport layer, and an electron injection layer. The light emitting layer may include an organic material that emits light of a preset color. The organic material may emit light based on a potential difference between the pixel electrode ANO and the common electrode CAT.

The common electrode CAT may be disposed on the intermediate layer ML. The common electrode CAT may cover the pixel defining layer BPDL. The common electrode CAT may include a transparent conductive material. For example, the common electrode CAT may be a cathode electrode. In another example, the common electrode CAT may be an anode electrode.

Although it has been described that the light emitting element LED included in the display device 1000 includes the pixel electrode ANO, the intermediate layer ML, and the common electrode CAT, the disclosure is not limited thereto. For example, the light emitting element LED may include a micro light emitting diode, a nano light emitting diode, a quantum dot, a quantum rod, and the like.

The thin film encapsulation layer TFE may be disposed on the common electrode CAT. The thin film encapsulation layer TFE may protect the light emitting element LED from external moisture, heat, impact, and the like. The thin film encapsulation layer TFE may include an inorganic layer and an organic layer that are alternately disposed.

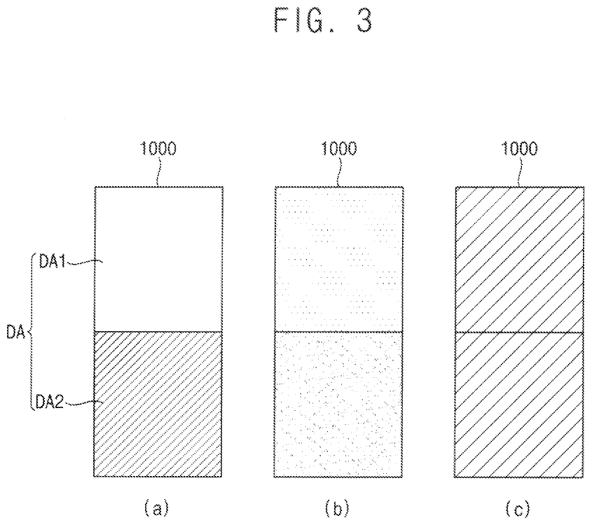

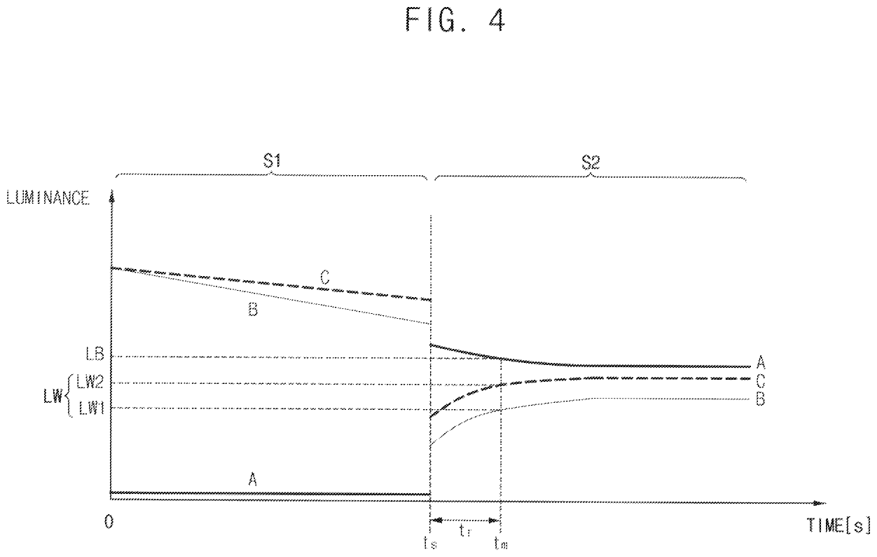

FIG. 3 is a schematic view for describing an afterimage of a display device, and FIG. 4 is a graph for explaining a long-term afterimage of a display device. The X-axis of the graph of FIG. 4 represents time, and the Y-axis represents the luminance of each of the first area DA1 and the second area DA2 of FIG. 3.

Referring to FIG. 3, the display area DA (refer to FIG. 1) of the display device 1000 may include a first area DA1 and a second area DA2 adjacent to the first area DA1.

Referring to FIG. 4, graphs A and B show cases where the charge trap layer AI is not disposed and the pixel defining layer BPDL does not have a black color. A graph of C shows a case where the charge trap layer AI is disposed and the pixel defining layer BPDL has a black color.

Referring to FIGS. 3 and 4, a graph of A represents the luminance of the second area DA2 of FIG. 3 over time. A graph of B shows the luminance of the first area DA1 of FIG. 3 over time. The graph of C represents the luminance of the first area DA1 of FIG. 3 over time.

Referring to FIGS. 3 (a) and 4, in the graphs A and B, during the stress time (ts), the first area DA1 may display a white pattern, and the second area DA2 may display a black pattern. A section before the stress time (ts) may be referred to as a stress section (S1). For example, the stress time (ts) may be in a range of about 10 seconds to about 30 minutes.

In the stress section S1, the first area DA1 may receive a signal to display a white pattern. The luminance of the first area DA1 may decrease as time passes. A phenomenon that the luminance of the first area DA1 receiving a signal to display a white pattern is reduced may be referred to as a luminance drop phenomenon.

Referring to FIGS. 3 (b) and 4, in the graph A and the graph B, at the stress time (ts), the first area DA1 and the second area DA2 may receive a signal to display a gray pattern. For example, the signal may cause the first area DA1 and the second area DA2 to display a 31 gray pattern. However, the first area DA1 and the second area DA2 may display different patterns at the stress time (ts) in case that the signal is received.

Referring to FIGS. 3 (c) and 4, in the graph A and the graph B, the section after the stress time (ts) may be referred to as a monitoring section (S2). In the monitoring section (S2), the luminance of the first area DA1 and the luminance of the second area DA2 may be different from each other. As a result, an afterimage may occur. The long-term afterimage may mean an afterimage generated in case that the stress time (ts) is about 3 minutes to about 30 minutes.

In the monitoring section S2, the luminance of the first area DA1 may gradually increase as time passes, and the luminance of the second area DA2 may decrease gradually as time passes. For example, the luminance of the first area DA1 and the luminance of the second area DA2 may approach a gray pattern (e.g., a 31 gray pattern) as time passes.

The monitoring time (tm) may be a time point in case that the release time (tr) has elapsed from the stress time (ts). At the monitoring time (tm), the first area DA1 may display the first luminance LW, and the second area DA2 may display the second luminance LB.

At the monitoring time (tm), a degree of afterimage TCR may be defined by the first luminance LW and the second luminance LB. For example, the degree of afterimage TCR may be defined at the monitoring time (tm) in case that the stress time (ts) is about 3 minutes to about 30 minutes and the release time (tr) is about 0 seconds to about 300 seconds. Accordingly, the degree of afterimage TCR may be an indicator for determining improvement of the long-term afterimage. The degree of afterimage TCR may be defined by Equation 1 below.

$$TCR = \frac{LB - LW}{LB + LW} \times 100 ( \% ) \qquad 〈 Equation 1 〉$$

In case that the absolute value of the degree of afterimage TCR is large, the long-term afterimage may remain, and in case that the absolute value of the degree of afterimage TCR is small, the long-term afterimage may not remain. For example, as the degree of afterimage TCR is closer to 0, the long-term afterimage may be improved. For example, in case that the difference between the first luminance LW and the second luminance LB is relatively large, the long-term afterimage may remain. In case that the difference between the first luminance LW and the second luminance LB is relatively small, the long-term afterimage may not remain.

A normal afterimage may mean that the degree of afterimage TCR is negative. The normal afterimage may be a case where the luminance of the first area DA1 is greater than the luminance of the second area DA2 in the monitoring section (S2). An inverse afterimage may mean that the degree of afterimage (TCR) is positive. The inverse afterimage may be a case where the luminance of the first area DA1 is smaller than the luminance of the second area DA2 in the monitoring section (S2).

In the monitoring section (S2), comparing the graph B and the graph C, the difference LB-LW2 between the first luminance LW2 and the second luminance LB (refer to graph C), which is the case where the charge trap layer AI is disposed, is smaller than the difference LB-LW1 between the first luminance LW1 and the second luminance LB, which is the case where the charge trap layer AI is not disposed (refer to graph B). Accordingly, by disposing the charge trap layer AI, the long-term afterimage may be improved.

In case that the charge trap layer AI is disposed, the threshold voltage of the second transistor TR2 (refer to FIG. 2) may increase as the driving range of the first transistor TR1 (refer to FIG. 2) is increased. In case that the threshold voltage of the second transistor TR2 increases, a kickback of the second transistor TR2 may increase. Accordingly, the luminance of the pixel PX may decrease, and the light efficiency of the display device 1000 (refer to FIG. 1) may decrease.

In the stress section (S1) of FIG. 4, comparing the graph B and the graph C, a degree of decrease in luminance where the pixel defining layer BPDL has a black color (refer to graph C) is smaller than the degree of decrease in luminance where the pixel defining layer BPDL does not have a black color (refer to graph B). Accordingly, as the pixel defining layer BPDL has a black color, the luminance drop phenomenon may be improved.

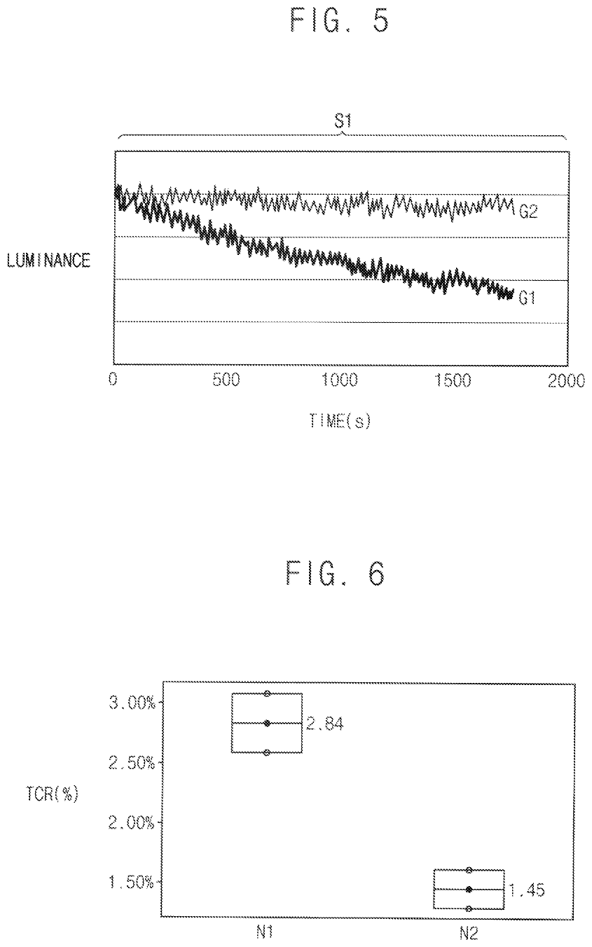

FIG. 5 is a graph illustrating an example of FIG. 4. FIG. 5 is a graph illustrating the stress section (S1) of FIG. 4.

Referring to FIG. 5, a graph G1 shows a case where the pixel defining layer BPDL does not have a black color. A graph G2 shows a case where the pixel defining layer BPDL has a black color.

In case that the pixel defining layer BPDL does not have a black color (refer to graph G1), the degree of decrease in luminance may be relatively large. In case that the pixel defining layer BPDL has a black color (refer to graph G2), the degree of decrease in luminance may be relatively small or the luminance may not substantially decrease. For example, since the pixel defining layer BPDL has a black color, the luminance drop phenomenon may be improved. In case that the luminance drop phenomenon is improved, the threshold voltage of the second transistor TR2 (refer to FIG. 2) may decrease. Accordingly, in case that the charge trap layer AI (refer to FIG. 2) is disposed and the pixel defining layer BPDL has a black color, the long-term afterimage may be improved, and the decrease in luminance of the pixel PX (refer to FIG. 1) and the decrease in light efficiency of the display device 1000 (refer to FIG. 1) may be compensated.

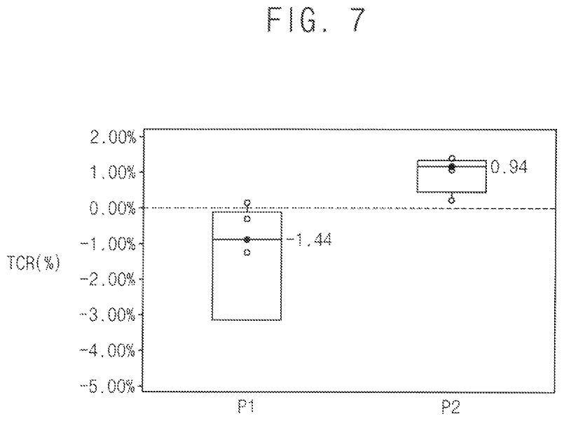

FIG. 6 is a graph illustrating a degree of an afterimage depending on whether a pixel defining layer has a black color according to an embodiment.

Referring to FIG. 6, a graph N1 shows a case where the pixel defining layer BPDL does not have a black color. A graph N2 shows a case where the pixel defining layer BPDL has a black color. In the graphs N1 and N2, the first active pattern ACT1 of the first transistor TR1 (refer to FIG. 2) and the second active pattern ACT2 of the second transistor TR2 (refer to FIG. 2) may include polycrystalline silicon.

The graph N1 and the graph N2 show the degree of afterimage (TCR) in case that the stress time (ts) is 30 minutes and the release time (tr) is 300 seconds. For example, the improvement of the long-term afterimage may be determined by the degree of the afterimage (TCR) of the graph N1 and the degree of the afterimage (TCR) of the graph N2.

In the graph N1, the degree of afterimage (TCR) has an average value of approximately 2.84. In the graph N2, the degree of afterimage (TCR) has an average value of approximately 1.45.

Comparing the graph N1 and the graph N2, in case that the pixel defining layer BPDL has a black color (refer to graph N2), the degree of afterimage is smaller than in case that the pixel defining layer BPDL does not have a black color (refer to graph N1). Accordingly, as the pixel defining layer BPDL has a black color, the long-term afterimage may be further improved. The improvement of the long-term afterimage is not limited to a case where the stress time (ts) is 30 minutes and the release time (tr) is 300 seconds. For example, even in case that the stress time (ts) is about 3 minutes to about 30 minutes and the release time (tr) is about 0 seconds to about 300 seconds, as the pixel defining layer BPDL has a black color, the long-term afterimage may be improved.

FIG. 7 is a graph illustrating a degree of an afterimage depending on whether a pixel defining layer has a black color, according to an embodiment.

Referring to FIG. 7, a graph P1 shows a case where the pixel defining layer BPDL does not have a black color. A graph P2 shows a case where the pixel defining layer BPDL has a black color. The graph P1 and the graph P2 show where the first active pattern ACT1 of the first transistor TR1 (refer to FIG. 2) includes polysilicon and the second active pattern ACT2 of the second transistor TR2 (refer to FIG. 2) includes an oxide semiconductor.

The graph P1 and the graph P2 show the degree of afterimage (TCR) in case that the stress time (ts) is 30 minutes and the release time (tr) is 300 seconds. For example, the improvement of the long-term afterimage may be determined by the degree of afterimage (TCR) of the graph of P1 and the degree of afterimage (TCR) of the graph of P2.

In the graph P1, the degree of afterimage (TCR) has an average value of approximately −1.44. Since the degree of afterimage (TCR) is negative, the normal afterimage is generated. The normal afterimage may lower display quality more than the inverse afterimage. Therefore, it is necessary to prevent the normal afterimage.

In the graph P2, the degree of afterimage (TCR) has an average value of about 0.94. Since the degree of afterimage (TCR) is a positive number, the normal afterimage does not occur.

Comparing the graph P1 and the graph P2, in case that the pixel defining layer BPDL has a black color (refer to graph P2), an absolute value of the degree of afterimage (TCR) is smaller than an absolute value of the degree of afterimage (TCR) in case that the pixel defining layer BPDL does not have a black color (refer graph of P1). In case that the pixel defining layer BPDL has a black color (refer to the graph P2), the normal afterimage is not generated. Accordingly, as the pixel defining layer BPDL has a black color, the long-term afterimage may be further improved and display quality of the display device 1000 may be improved.

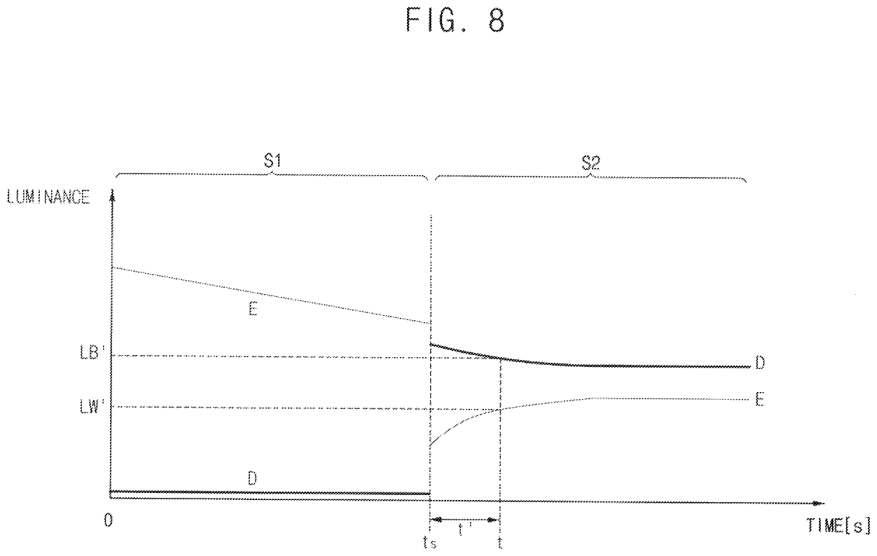

FIG. 8 is a graph for explaining an instantaneous afterimage of a display device. The X-axis of the graph of FIG. 8 represents time, and the Y-axis represents the luminance of each of the first area DA1 and the second area DA2 of FIG. 3.

Referring to FIGS. 3 and 8, a graph D shows the luminance of the second area DA2 of FIG. 3 over to time. A graph E shows the luminance of the first area DA1 of FIG. 3 over to time.

In the monitoring section (S2), the luminance of the first area DA1 and the luminance of the second area DA2 may be different from each other. As a result, an afterimage may occur. The instantaneous afterimage may mean an afterimage generated in case that the stress time (ts) is in a range of about 10 seconds to about 90 seconds.

The afterimage time (t′) may be an interval between the time point (t) and the stress time (ts). At a time point (t) when the afterimage time (t′) has elapsed from the stress time (ts), the first area DA1 may display the first luminance LW′, and the second area DA2 may display the second luminance LB′. The afterimage time (t′) may be defined in case that the stress time (ts) is about 10 seconds to about 90 seconds. Accordingly, the afterimage time (t′) may be an indicator for determining the improvement of the instantaneous afterimage. The afterimage time (t′) may be defined by the time point (t) that satisfies Equation 2 below.

$$\vert \frac{{LB}^{′} - {LW}^{′}}{{LB}^{′} + {LW}^{′}} \vert = 0.004 \qquad 〈 Equation 2 〉$$

At the time point (t) that satisfies Equation 2, the user may not recognize the difference between the first luminance LW′ of the first area DA1 and the second luminance LB′ of the second area DA2. Accordingly, the instantaneous afterimage may not remain after the afterimage time (t′) has elapsed from the stress time (ts). For example, the instantaneous afterimage may be improved as the afterimage time (t′) is smaller. For example, the afterimage time (t′) may be a time taken for the instantaneous afterimage to disappear.

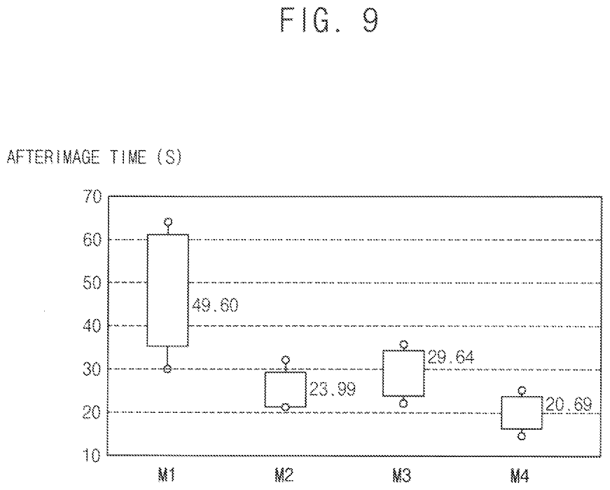

FIG. 9 is a graph illustrating an afterimage time depending on whether a pixel defining layer has a black color, according to an embodiment.

Referring to FIGS. 8 and 9, a graph M1 and a graph M2 show the afterimage time (t′) in case that the stress time (ts) is 90 seconds. A graph M3 and a graph M4 show the afterimage time (t′) in case that the stress time (ts) is 10 seconds. For example, the improvement of the instantaneous afterimage may be judged by the afterimage time (t′) of the graph M1, the afterimage time (t′) of the graph M2, the afterimage time (t′) of the graph M3, and the afterimage time (t′) of the graph M4

The graph M1 and the graph M3 show a case where the pixel defining layer BPDL does not have a black color. The graph of M2 and the graph of M4 show a case where the pixel defining layer BPDL has a black color.

In the graph M1, the afterimage time (t′) has an average value of approximately 49.60. In the graph M2, the afterimage time (t′) has an average value of approximately 23.99. In the graph M3, the afterimage time (t′) has an average value of approximately 29.64. In the graph M4, the afterimage time (t′) has an average value of approximately 20.69.

Comparing the graph M1 and the graph M2, in case that the pixel defining layer BPDL has a black color (refer to graph M2), the afterimage time is shorter than the case where the pixel defining layer BPDL does not have a black color (refer to graph M1). Comparing the graph M3 and the graph M4, in case that the pixel defining layer BPDL has a black color (refer to graph M4), the afterimage time is shorter than the case where the pixel defining layer BPDL does not have a black color (refer to graph M3). Accordingly, as the pixel defining layer BPDL has a black color, the instantaneous afterimage may be improved. For example, in case that the pixel defining layer BPDL has a black color, not only the long-term afterimage but also the instantaneous afterimage may be improved.

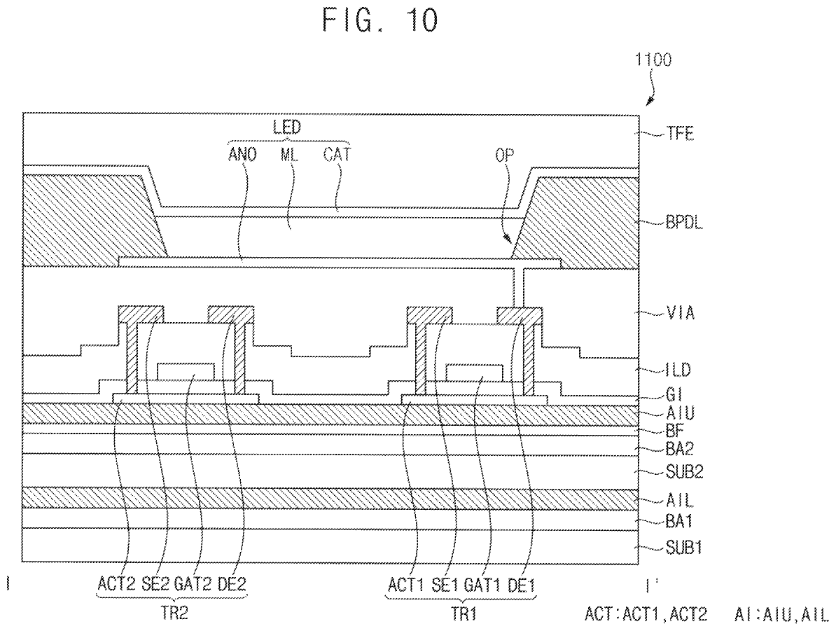

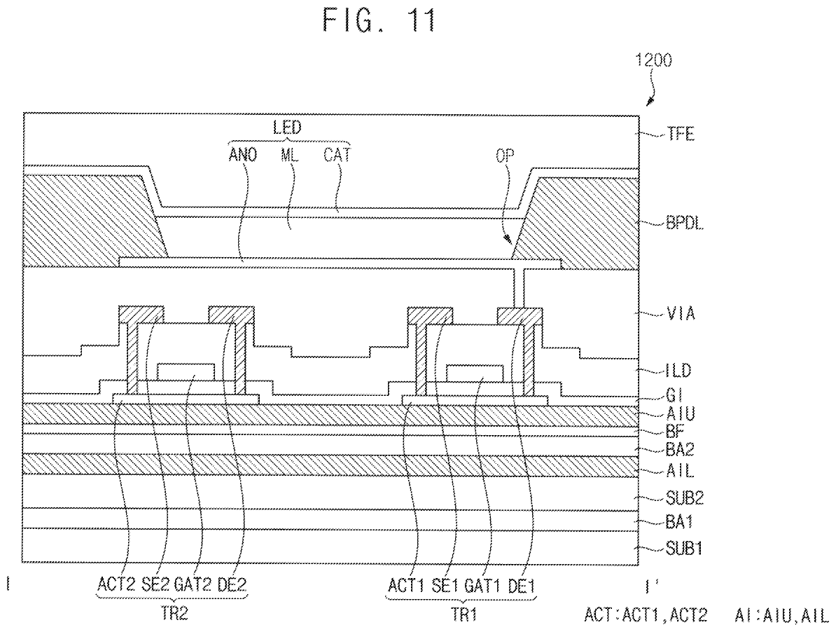

FIG. 10 is a schematic cross-sectional view illustrating a display device according to an embodiment.

Referring to FIG. 10, a display device 1100 according to an embodiment may be substantially the same as the display device 1000 described with reference to FIG. 2 except for the charge trap layer AI. Accordingly, overlapping descriptions will be omitted.

The charge trap layer AI may include an upper charge trap layer AIU and a lower charge trap layer AIL.

The upper charge trap layer AIU may be disposed on the buffer layer BF. The upper charge trap layer AIU may include an inorganic material. In an embodiment, the upper charge trap layer AIU may include silicon oxide (SiOx). However, the inorganic material is not limited to silicon oxide, and may be silicon nitride, silicon oxynitride, or the like.

In case that the upper charge trap layer AIU includes silicon oxide, the upper charge trap layer AIU may be formed by chemical vapor deposition. The upper charge trap layer AIU may be formed by adjusting the input amounts of nitrous oxide (N₂O) and silane (SiH₄). Accordingly, the upper charge trap layer AIU may include a hydrogen atom (H) and a nitrogen atom (N) in addition to an oxygen atom (O) and a silicon atom (Si).

In case that the upper charge trap layer AIU includes silicon oxide, the ratio of N—H bond in the upper charge trap layer AIU may be about 0.3 at % or less, or about 0.1 at % to about 0.2 at %. However, the ratio of the N—H bond in the upper charge trap layer AIU is not limited thereto.

In case that the upper charge trap layer AIU includes silicon oxide, the oxygen atom content in the upper charge trap layer AIU may be about 55.27 at %, or in a range of about 54 at % to about 56 at %. The silicon atom content in the upper charge trap layer AIU may be about 44.72 at %, or in a range of about 43 at % to about 45 at %.

In an embodiment, the upper charge trap layer AIU may be in contact with the semiconductor layer ACT.

In an embodiment, the lower charge trap layer AIL may be disposed between the first barrier layer BA1 and the second substrate SUB2. The lower charge trap layer AIL may include an inorganic material. In an embodiment, the lower charge trap layer AIL may include silicon nitride (SiNx). However, the inorganic material is not limited to silicon nitride, and may be silicon oxide, silicon oxynitride, or the like.

The lower charge trap layer AIL may serve to more firmly bond the first substrate SUB1 and the second substrate SUB2 to each other.

The lower charge trap layer AIL may be formed by chemical vapor deposition. In case that the lower charge trap layer AIL includes silicon nitride, the lower charge trap layer AIL may be formed under an ammonia-free (NH₃ free) condition. For example, the lower charge trap layer AIL may be formed by adjusting the input amounts of nitrogen (N₂) and silane (SiH₄). The lower charge trap layer AIL may include a hydrogen atom (H) in addition to a nitrogen atom (N) and a silicon atom (Si). In an embodiment, ammonia (NH₃) may not be added.

In case that the lower charge trap layer AIL is formed in an ammonia-free condition, a refractive index of the lower charge trap layer AIL may be about 2.7774, in a range of about 2.3 to about 3.0, or in a range of about 2.0 to about 3.5, but is not limited thereto.

In case that the lower charge trap layer AIL includes silicon nitride, the ratio of N—H bond in the lower charge trap layer AIL may be about 1.05 at %, in a range of about 1 at % to about 5 at %, or in a range of about 0.1 at % to about 15 at %. However, the ratio of the N—H bond in the lower charge trap layer AIL is not limited thereto.

The ratio of Si—H bond in the lower charge trap layer AIL may be about 10.02 at %, in a range of about 8 at % to about 12 at %, or in a range of about 8 at % to about 15 at %. However, the ratio of the Si—H bond in the lower charge trap layer AIL is not limited thereto. The ratio of Si—H bond may mean a ratio of bonds in which a silicon atom (Si) and a hydrogen atom (H) are bonded among all bonds.

The ratio of the Si—H bond in the lower charge trap layer AIL to the ratio of the N—H bond in the lower charge trap layer AIL ([Si—H]/[NH]) may be about 9.54, in a range of about 8 to about 12, or in a range of about 8 to about 15.

The ratio of N—H bond, the ratio of Si—H bond, and/or the ratio of Si—H bond to the ratio of N—H bond may be analyzed through a Fourier transform infrared spectrometer (FT-IR spectrometer).

The silicon atom content in the lower charge trap layer AIL may be about 65.05 at %, in a range of about 60 at % to about 70 at %, or in a range of about 50 at % to about 80 at %. The nitrogen atom content in the lower charge trap layer AIL may be about 31.85 at %, in a range of about 25 at % to about 35 at %, or in a range of about 20 at % to about 40 at %. The ratio of the silicon atom content in the lower charge trap layer AIL to the nitrogen atom content in the lower charge trap layer AIL may be about 2.04, in a range of about 1.6 to about 2.5, or in a range of about 1.1 to about 3.0.

The silicon atom content, the nitrogen atom content, and the ratio of the silicon atom content to the nitrogen atom content may be analyzed through energy dispersion x-ray spectrometry (EDS).

The element characteristics of the first transistor TR1 may be improved. For example, the driving range of the first transistor TR1 may increase. Accordingly, the luminance of the display device 1100 may be improved, and the long-term afterimage may be improved.

In case that the range is smaller than the above-mentioned range, the improvement in the element characteristics of the first transistor TR1 may not be significant, and in case that it is larger than the above-mentioned range, the lower charge trap layer AIL may not be properly formed.

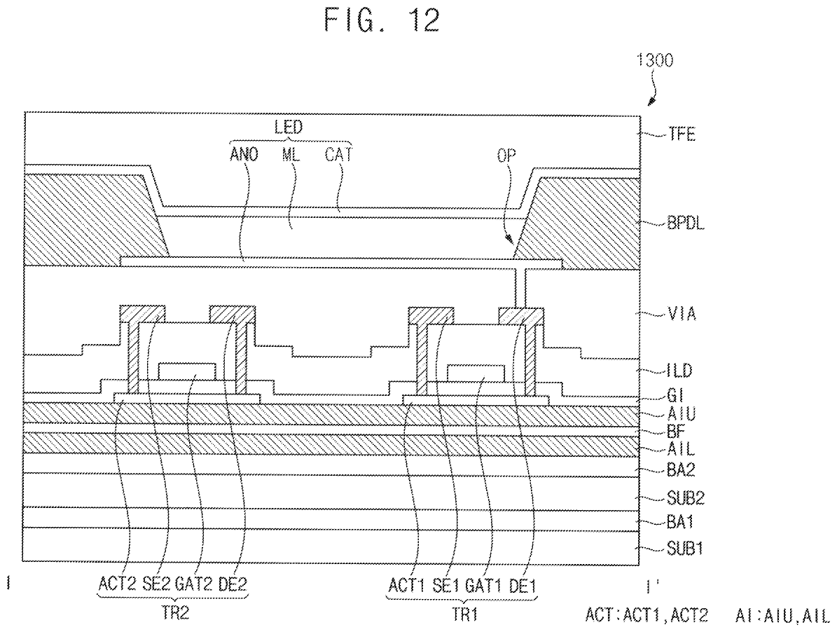

FIG. 11 is a schematic cross-sectional view illustrating a display device according to an embodiment.

Referring to FIG. 11, a display device 1200 according to another embodiment may be substantially the same as the display device 1100 described with reference to FIG. 10 except for the lower charge trap layer AIL. Accordingly, overlapping descriptions will be omitted.

In an embodiment, the lower charge trap layer AIL may be disposed between the second substrate SUB2 and the second barrier layer BA2.

As the lower charge trap layer AIL and the upper charge trap layer AIU are disposed, the element characteristics of the first transistor TR1 may be improved. For example, the driving range of the first transistor TR1 may increase. Accordingly, the luminance of the display device 1200 may be improved, and the long-term afterimage may be improved.

FIG. 12 is a schematic cross-sectional view illustrating a display device according to an embodiment.

Referring to FIG. 12, a display device 1300 according to an embodiment of the disclosure may be substantially the same as the display device 1100 described with reference to FIG. 10 except for the lower charge trap layer AIL. Accordingly, overlapping descriptions will be omitted.

In an embodiment, the lower charge trap layer AIL may be disposed between the second barrier layer BA2 and the buffer layer BF.

As the lower charge trap layer AIL and the upper charge trap layer AIU are disposed, the element characteristics of the first transistor TR1 may be improved. For example, the driving range of the first transistor TR1 may increase. Accordingly, the luminance of the display device 1300 may be improved, and the long-term afterimage may be improved.

The disclosure should not be construed as being limited to the embodiments set forth herein. Rather, these embodiments are provided so that this disclosure will be thorough and complete and will fully convey the disclosure to those skilled in the art.

Embodiments have been disclosed herein, and although terms are employed, they are used and are to be interpreted in a generic and descriptive sense only and not for purpose of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the following claims.

What is claimed is:

1. A display device, comprising:
a first barrier layer disposed on a first substrate;
a second substrate disposed on the first barrier layer;
a second barrier layer disposed on the second substrate;
a buffer layer disposed on the second barrier layer;
an upper charge trap layer disposed on the buffer layer, the upper charge trap layer including silicon oxide, and having an oxygen atom content in a range of about 54 at % to about 56 at %;
a semiconductor layer disposed on the upper charge trap layer;
a pixel electrode disposed on the semiconductor layer and electrically connected to the semiconductor layer;
a pixel defining layer disposed on the pixel electrode, the pixel defining layer including an opening exposing a portion of the pixel electrode, and having a black color;
an intermediate layer disposed on the pixel electrode and disposed in the opening; and
a common electrode disposed on the intermediate layer.

2. The display device of claim 1, wherein the pixel defining layer includes a black pigment.

3. The display device of claim 2, wherein the black pigment includes carbon black.

4. The display device of claim 1, wherein an optical density of the pixel defining layer is about 1.

5. The display device of claim 1, wherein at least a portion of the pixel defining layer overlaps the semiconductor layer.

6. The display device of claim 1, wherein
the upper charge trap layer includes a hydrogen atom (H) and a nitrogen atom (N), and
a ratio of N—H bonds in the upper charge trap layer is about 0.3 at % or less.

7. The display device of claim 1, further comprising:
a lower charge trap layer disposed between the first substrate and the buffer layer, the lower charge trap layer including silicon nitride.

8. The display device of claim 7, wherein the lower charge trap layer is formed under an ammonia-free (NH₃ free) condition.

9. The display device of claim 7, wherein a ratio of a silicon atom content in the lower charge trap layer to a nitrogen atom content in the lower charge trap layer is in a range of about 1.6 to about 2.5.

10. The display device of claim 7, wherein
a silicon atom content in the lower charge trap layer is in a range of about 60 at % to about 70 at %, and
a nitrogen atom content in the lower charge trap layer is in a range of about 25 at % to about 35 at %.

11. The display device of claim 7, wherein a ratio of Si—H bond in the lower charge trap layer is in a range of about 8 at % to about 15 at %.

12. The display device of claim 7, wherein a ratio of the Si—H bond in the lower charge trap layer to the N—H bond in the lower charge trap layer is in a range of about 8 to about 15.

13. The display device of claim 7, wherein the lower charge trap layer is disposed between the first barrier layer and the second substrate.

14. The display device of claim 7, wherein the lower charge trap layer is disposed between the second substrate and the second barrier layer.

15. The display device of claim 7, wherein the lower charge trap layer is disposed on the second barrier layer.

16. The display device of claim 1, wherein the first barrier layer and the second barrier layer include silicon oxide.

17. The display device of claim 1, wherein the first substrate and the second substrate include polyimide.

18. The display device of claim 1, wherein the upper charge trap layer is in contact with the semiconductor layer.

19. The display device of claim 1, wherein the buffer layer includes silicon nitride.

20. The display device of claim 1, wherein the semiconductor layer includes polycrystalline silicon or an oxide semiconductor.
